(19) United States
(12) Patent Application Publication
(10) Pub. No.: US 2019/0341549 A1
(43) Pub. Date: Nov. 7, 2019

(54) RESISTIVE SWITCHING MEMORY

(71) Applicant: Australian Advanced Materials Pty Ltd, Subiaco (AU)

(72) Inventors: Charles Murphy, Subiaco (AU); Sean Suixiang Li, Turramurra (AU); Dewei Chu, Kensington, New South Wales (AU); Nicholas John White, London (GB)

(73) Assignee: Australian Advanced Materials Pty Ltd, Subiaco (AU)

(21) Appl. No.: 16/466,699

(22) PCT Filed: Dec. 7, 2017
(86) PCT No.: PCT/AU2017/051348

§ 371 Date: Jun. 5, 2019

(30) Foreign Application Priority Data
Dec. 7, 2016 (GB) 1620835.7

(51) Int. Cl. H01L 45/00; H01L 27/24

(52) U.S. Cl. CPC H01L 45/146; H01L 27/2463; H01L 45/1608; H01L 45/122; H01L 45/1253; H01L 45/08

(57) ABSTRACT

Non-volatile Resistive RAM devices are described prepared using various nanocube dispersions and dispersion based deposition techniques including ink jet printing. Stretchable Resistive RAM devices are described that retain their switching properties after repeated stretch and relaxation cycles and show highly stable ON/OFF ratios after each cycle in the stretched and relaxed state.

### FIELD OF INVENTION

The present invention relates generally to non-volatile memories and more specifically to resistive-switching memory devices also known as Resistive RAM.

### BACKGROUND ART

Non-volatile memories are memories that retain their contents when unpowered. They may be used for storage in a wide variety of devices that require persistent data storage. These non-volatile memories may often take the form of removable and portable memory cards or other memory modules. They may also be integrated into other types of circuits or devices. Non-volatile semiconductor memories are receiving increasing attention because of their advantages in being small in size, exhibiting data persistence, having no moving parts and their need for little power for operation.

One of the more common and interesting types of non-volatile memory is flash memory. Flash memory is however often proving to be inadequate for many and emerging non-volatile memory applications. One alternative to conventional flash non-volatile memory technology is the area of resistive-switching memory. These are typically memory devices that include a resistive-switching material (e.g. a metal oxide) that changes from a first resistivity to a second resistivity upon the application of a set voltage, and from the second resistivity back to the first resistivity upon the application of a reset voltage.

Resistive Random Access Memory (often abbreviated to ReRAM or RRAM) is emerging as one of the most promising technologies for non-volatile memory. These types of memory are often characterized by their simple structure, high operation speed, low power consumption, feasibility of vertical stacking and good compatibility with the current complementary metal oxide semiconductor (CMOS) technology and related technologies.

Despite recent developments there is a continuing need for alternative ReRAM materials, structures and methods for their manufacture.

### DISCLOSURE OF THE INVENTION

The present invention in general and in various embodiments is directed to a resistive switching memory unit that is based on the presence of particulate metal oxides within its structure and the use of particulate metal oxide materials in its manufacture. Various aspect and embodiments of resistive-switching memory units are described herein. The memory units generally have but are not limited to a metal-insulator-metal (MIM) structure in which resistive-switching layers are surrounded by two conductive electrodes, but they may also have other structures such as metal-insulator-insulator-metal (MIIM) or metal-insulator-metal-insulator (MIMIM) and other structures.

Embodiments of the invention relate to a memory structure that preferably utilize metal oxide nanocrystals. Preferably such embodiments are rewritable, non-volatile and/or flexible, stretchable and include a resistive random access memory cell structure which is able to store one or more binary bits of data.

In a first embodiment of the present invention there is provided a resistive-switching memory unit comprising a first electrode, a second electrode and resistive switching material located between the first and second electrodes and wherein the resistive switching material comprises doped particulate metal oxide.

In a second embodiment of the present invention there is provided a resistive-switching memory unit comprising a first electrode, a second electrode and resistive switching material located between the first and second electrodes and wherein the resistive switching material comprises a mixture of doped particulate metal oxide and undoped particulate metal oxide.

In a third embodiment of the present invention there is provided a resistive-switching memory unit comprising a first electrode, a second electrode and resistive switching material located between the first and second electrodes and wherein the resistive switching material comprises at least one layer of particulate metal oxide and at least one layer of non-particulate metal oxide. The resistive switching material is a hybrid resistive switching material consisting of one or more layers of particulate metal oxide deposited by liquid solution or dispersion deposition techniques and one or more layers of a non-particulate metal oxide that is typically amorphous and has been deposited using conventional semiconductor manufacturing techniques. The non-particulate metal oxide layer may be replaced by other material layers comprising materials that may typically be used in semiconductor manufacture; organic and/or inorganic materials such as for example conductive or semi-conductive polymers or nitrite compound materials or intermetallic materials may be used. These materials may also be used to provide additional layers in the resistive-switching memory unit.

In a fourth embodiment of the present invention there is provided a resistive-switching memory unit comprising a first electrode, a second electrode and resistive switching material located between the first and second electrodes and wherein the resistive switching material comprises particulate metal oxide and the resistive-switching memory unit has at least one low (LRS) and one high (HRS) resistance state and exhibits an HRS/LRS resistance ratio of 10⁵ or greater. Preferably a ratio of 10⁶ or greater.

In a fifth embodiment of the present invention there is provided a resistive-switching memory unit comprising a first electrode, a second electrode and resistive switching material located between the first and second electrodes and wherein the resistive switching material comprises particulate metal oxide and the resistive-switching memory unit has a switch voltage of 2 volts or less. Preferably 1 volt or less.

In a sixth embodiment of the present invention there is provided a stretchable memory device which comprises a resistive-switching memory unit comprising a first electrode, a second electrode and resistive switching material located between the first and second electrodes, wherein the resistive switching layer comprises particulate metal oxide and the unit is attached to and supported by an elastomeric substrate. This stretchable memory device retains its memory performance after elongation of the elastomeric substrate and retains its memory function upon relaxation of the elastomeric substrate after an initial elongation. The memory performance may be retained after multiple cycles of stretching and relaxation and preferably is retained after 10 cycles or more of elongation and relaxation of the elastomeric substrate and most preferably after 100 cycles or more of elongation and relaxation of the elastomeric substrate. In a preferred embodiment the stretchable memory device retains its memory performance after multiple cycles of elongation and relaxation of the elastomeric substrate and wherein the magnitude of elongation and relaxation of the substrate at each cycle is varied.

In a seventh embodiment of the present invention there is provided a method for manufacturing a stretchable memory device, which method comprises depositing a first electrode upon a stretchable substrate, depositing resistive switching material comprising particulate metal oxide upon the first electrode and depositing a second electrode upon the resistive switching material.

In an eight embodiment, there is provided a deformable memory device which comprises a resistive-switching memory unit comprising a first electrode, a second electrode and resistive switching material located between the first and second electrodes, wherein the resistive switching material comprises particulate metal oxide and the unit is attached to and supported by a deformable substrate.

In a ninth embodiment, there is provided a method for manufacturing a deformable memory device, which method comprises depositing a first electrode upon a deformable substrate, depositing resistive switching material comprising particulate metal oxide upon the first electrode and depositing a second electrode upon the resistive switching material and inducing inelastic deformation of the substrate.

In all embodiments of the present invention where the switching layer comprises particulate metal oxide the particulate metal oxide is preferably present in the form of one or more layers and preferably comprises one or more 2D arrays of particles layered one on top of each other. In preferred embodiments, the particulate metal oxide is in the form of nanocubes. When the metal oxide present in the switching layer is not in particulate form, such as in particular the third embodiment, it is preferably present as a substantially discreet monolithic layer of material.

In all embodiments of the present invention the switching material may comprise paired layers of metal oxide to provide a paired switching layer; each layer within the pair being of a different composition. Preferably, the metal oxide present in the paired layers is in the form of particulate metal oxide save that in respect of the third embodiment there will also be present at least one non-particulate metal oxide as part of the paired switching layer. The resistive switching material comprising two adjacent layers of nanocubes of differing compositions is referred herein to as paired switching layer; thus, when two or more of these paired switching layers are stacked one upon another the resulting stack comprises alternating paired switching layers.

Such a paired switching layer may have and preferably do have multiple resistive states. In all embodiments of the present invention two or more paired switching layers may be present within the switching material. Preferably, these paired switching layers are arranged so that their individual layers alternate by composition between the electrodes. This alternating arrangement may provide for example an ABAB layer arrangement or similar between the electrodes; with this example having two alternating paired switching layers of AB. Other arrangements are possible. Increasing the number of alternating paired switching layers generally results in an increase in the number of resistive states of the memory device. Thus, memory device structures may be prepared of multiple resistive states and as a consequence provide compact memory devices.

As an example, the memory device structures of all embodiments of the present invention may have three, four, five or six or more alternating paired switching layers, sandwiched between bottom and top electrodes, to provide one memory unit. These complete memory units may, through the appropriate order of deposition of layers, be stacked one on top of each other to produce a stacked memory device. In some embodiments, the top electrode of one complete memory unit may simultaneously form the bottom electrode of a subsequently stacked complete memory unit structure and so on. In some embodiments, the stacked memory device may be arranged in various configurations including but not limited to a crossbar structure. Through stacking of the memory units, higher data storage capacity may be realized.

Each complete memory unit may have high, low and intermediate resistive states. By positioning layers of particulate or when present non-particulate metal oxide materials of different composition next to each other multiple resistive states can be achieved. The highest and the lowest resistance states are known as HRS and LRS, respectively. Any resistive states that are present between the HRS and LRS values are known as intermediate resistive states.

In the present invention, the number of resistive states may be tuned by adjusting the number of layers in the memory unit and/or by altering the relative material compositions of the layers within each memory unit. By adjusting the layer structure and/or composition, tunable resistive states may be realized. A multi-level memory structure may be achieved by increasing the number of paired switching layers in the unit or in some embodiments by the simple presence of unpaired layers of material. When fabricated, the number and resistance value of the resistive states that may be realized in the memory unit structure are permanently set and do not change and are stable. The memory unit structure can therefore be used in memory devices, which utilize resistive states to store data.

The memory units of the present invention will therefore typically during use have a minimum of two resistive states as indicated above; namely a High Resistive State (HRS) and a Low Resistive State (LRS). VSET and VRESET voltages are used to switch between HRS and LRS. Appropriate circuitry and electronics are used to detect the resistive state of the memory unit and to switch between HRS and LRS. During use the state of the memory (HRS or LRS) may be determined through use of a sensing voltage VSENSE. The resistive state namely HRS or LRS is selected to be logic one and logic zero to provide a 1 bit device. If there are multiple resistive states other than HRS and LRS then the device may be operated as 2 or higher bit devices depending on the number of resistive states present in the memory unit. Once the resistive state has been determined at the read stage a write operation can be instigated to induce a change of resistive state in the memory unit using either the VSET or VRESET voltage. The resistive state selected is stable after application of VSET or VRESET and so is in essence is a non-volatile memory unit. It is desirable that the resistance gap between HRS and LRS are relatively large and that they are as discreet as possible. In some devices prior to use for memory storage the unit may be exposed to a forming voltage VFORM, which is typically greater than the VSET voltage or VRESET voltage used for the memory storage cycle. The memory unit is initially set using an appropriate VFORM voltage and then the VSET and VRESET voltages are used to switch between HRS and LRS.

In the present invention, the resistive switching material comprises one or more doped particulate metal oxides and/or un-doped particulate metal oxides. These particulate metal oxides may be amorphous, semi-crystalline and/or crystalline materials. It is preferred that they are semi-crystalline and/or crystalline and most preferably are crystalline. If any embodiment makes reference to particulate metal oxide it should be understood that this may include doped or undoped metal oxides or mixtures thereof.

Un-doped metal oxides are essentially pure materials that have been manufactured to provide as best as possible a pure particulate form of the oxide in question. In the case of crystalline particulate metal oxides, the crystal lattice structure does not include any other materials other than the elements of the relevant oxide in stoichiometric proportions.

Doped metal oxides may be materials that have been manufactured in the presence of another material or post treated with another material that may in part be incorporated into the structure of the particulate material. In the case of crystalline particulate metal oxides, the crystal lattice will have certain atoms displaced and replaced by atoms of the other material; thus, the lattice will for example include other metal atoms in the lattice and the resultant metal oxide will not be purely stoichiometric in terms of the components of the standard metal oxide; the lattice is doped with a level of the other metal. Doped metal oxides may also encompass materials where there has been no metal exchange of the core metal of the metal oxide with the dopant metal; in this case any doping metal may be present in the interstitial sites of the core material of the particle. For example, this may typically occur when the metal dopant is smaller than the core metal of the metal oxide. Both forms of doped metal oxide are suitable for the embodiments of the present invention.

The doped or un-doped particulate metal oxide may be of any shape. When the doped or un-doped particulate metal oxides are crystalline they may be of any crystal structure morphology. Suitable crystalline forms are cubic, tetragonal, trigonal, hexagonal, orthorhombic, monoclinic, triclinic, face centered cubic, face truncated cubic, face truncated octahedron or truncated octahedron. It is preferred that in all of the embodiments of the present invention that the crystalline metal oxides used (doped and un-doped) have a cubic based morphology and most preferably are face-to-face square cubic. The particulate metal oxide may also take the form of other shapes such as rods or fibers or a generally rectangular morphology in which there are at least two dimensions e.g. length and breadth, which are different.

The metal oxide particles or when present non-particulate metal oxide may comprise a semiconductor or dielectric or an insulator. The metal oxide may be any metal oxide that may be electrically induced to provide at least two resistive states. The metal oxide may be a transition metal oxide, an alkaline earth metal oxide, a post transition metal oxide, a metalloid oxide, a complex oxide and/ or a lanthanide oxide material. The metal oxide may, for example, binary oxides such as cerium(IV) oxide (CeO₂), indium(III) oxide (In₂O₃), or perovskite type oxides such as SrTiO₃, BaTiO₃ and calcium titanium oxide (CaTiO₃) or ternary metal oxides or more. Examples of suitable metal oxides for use as the metal oxide of the present invention are as disclosed by Kazumi, et.al, in Advanced Powder Technology, Volume 25, Issue 5, September 2014, Pages 1401-1414, the whole contents of which are hereby incorporated by reference. Other examples include hafnium oxide, aluminum oxide, tantalum oxide, zirconium oxide, and yttrium oxide. The preferred metal oxides are those that may form particulate metal oxides, particularly preferred are cubic particle forming metal oxides, that may self-assemble when deposited from and through solution/dispersion based compositions and methods.

In all embodiments of the present invention it is envisaged that the resistive switching material always comprises at least one particulate metal oxide material. Typically, this material is present as one or more layers within the resistive switching material to provide resistive switching function to the material. In is also envisaged that typically a paired switching layer will comprise two layers of different particulate metal oxide material. It is also envisaged that within the resistive switching material that one or more but not all of the particulate metal oxide layers may be replaced with a layer of any material other than metal oxide and this may or may not be in particulate form. Such materials may be any material that is typically used in semiconductor manufacturing techniques. Such materials may include organic and/or inorganic materials, such as conductive or semi-conductive material or organic or inorganic materials such as for example organic polymeric materials, nitrate compounds and/or intermetallic materials. These layers may be used to replace one or more particulate metal oxide layers or may be used in addition to one or more particulate metal oxide layers. It is envisaged that they may form part of a paired switching layer or may be present as an additional layer.

In all embodiments of the present invention the resistive switching material comprises at least one particulate metal oxide material, typically on layer form. As previously indicated such layers may comprise a pure form or one metal oxide or may comprise mixtures of pure forms of different metal oxides or may comprise mixtures of pure and doped forms of the metal oxide or may comprise mixtures of various doped metal oxides. These layers may therefore comprise a variety of compositions depending on the choice of core metal oxides, the nature and level of dopants present and the mixture of particles of different composition and form. It is also envisaged that the particulate metal oxide layers may comprise other materials in particulate or non-particulate form. These additional materials may be any material that is typically used in semiconductor manufacturing techniques. Such materials may include organic and/or inorganic materials, such as conductive or semi-conductive material; or organic or inorganic materials such as for example organic polymeric materials, nitrate compounds and/or intermetallic materials. When present organic polymeric materials may provide alternative electrical and physical properties to the memory unit in for example such embodiments where the substrate for the memory is flexible or elastic or deformable. The use of non-metal oxide particulates enables the properties of the particulate metal oxide layer to be altered modified and fine tuned to the desired electrical and physical properties for the end application for the memory unit.

In preferred embodiments, the resistive switching material comprises doped and/or un-doped lanthanide oxides and most preferably cerium(IV) oxide (CeO₂). Cerium(IV) oxide is a wide bandgap semiconductor and it is particularly attractive for use in a memory device because its properties are well suited to allowing a change in the resistive state in response to an electromotive force being applied thereto. Cerium(IV) dioxide (CeO₂) has a fluorite structure (FCC) with space group Fm3m and it consists of a simple cubic oxygen sub-lattice with the cerium ions occupying alternate cube centers.

In the preferred doped metal oxides for use in the present invention the dopant metal preferably has an ionic radius comparable to that of the core metal of the metal oxide (the host metal) that is substituted on doping. One advantage of the dopant having a similar ionic radius to the host metal is that there is less lattice distortion in the crystalline particle of the doped metal oxide. This is beneficial when the memory device of the present invention uses doped and un-doped crystalline metal oxides of the same core metal oxide e.g. doped and un-doped cerium(IV) oxide (CeO₂).

In those embodiments where doped metal oxide particles are used in the resistive switching material, their composition i.e. level or nature of dopant may be adjusted to tune the properties of the resistive switching material and in particular to tune the resistive states of the resistive switching material of the memory unit. In this regard, the addition of a dopant alters the way in which the metal oxide's electrical resistive state changes in response to an electromotive force. Thus it is envisaged in the present invention that layers of adjacent doped metal oxide may have particles of different composition but the composition of the particles in each layer is uniform i.e. the same level of dopant in each particle. It is also envisaged that for exclusively doped metal oxide systems each layer could have a mixture of metal oxide particles with different levels of dopant. It is also envisaged in the present invention that layers could be present in which the level of dopant within the layer is further controlled by mixing doped metal oxide particles (uniformly doped or a mixture of different doped metal oxide particles) with undoped metal oxide particles; as the level of undoped metal oxide particles is increased the effective level of dopant in the particle layer is diluted and reduced.

In the present invention, the amount of dopant in the doped metal oxides may be at various levels. The level may be selected to provide trace quantities of the dopant metal within the doped metal oxide, with trace in the context of the present invention being from 500 ppm. Typically, the dopant metal is present in the doped metal oxide at a level of from about 0.1 wt. % to about 30 wt. %. The dopant metal may be present in the doped metal oxide at a level of from about 1 wt. % to about 25 wt. %. Preferably the amount of dopant metal in the doped metal oxide is from about 2 wt. % to about 20 wt. %, more preferably from about 3 wt. % to about 15 wt. %. and most preferably from about 5 wt. % to about 15 wt. %.

Examples of suitable dopant metals include; indium (In), cobalt (Co), gadolinium (Gd), ytterbium (Yb), and samarium (Sm). The most preferred dopant metal is indium (In). Indium is particularly preferred as the dopant metal for cerium(IV) oxide (CeO₂). The valency of indium ions is +3, while the valency of cerium ions is usually +4; thus, more oxygen vacancies can be introduced in a doped metal oxide. In addition, using indium as a dopant in the doped metal oxide is believed to create charge traps which contribute to the realization of desirable intermediate resistive states, which means multiple resistive states can be achieved within the memory structure of the invention. The introduction of the intermediate resistive states may also result in a much higher HRS (high resistive state) value as well as a desirable higher on/off ratio. It is also believed that indium ions will have high mobility in these structures and can improve the response of the memory device of the present invention (i.e. switching speed). In the embodiments of the present invention the use of indium doped cerium particles as part of the resistive switching material has provided memory units with HRS/LRS resistance ratio of 10⁵ or greater or even 10⁶ or greater. Other dopants may include rare earth metals such as lanthanum, cerium, praseodymium, neodymium, erbium, and lutetium and their oxides. Additional dopants may include hafnium, hafnium oxide, titanium oxide, niobium oxide, oxygen, silicon, silicon oxide, nitrogen, fluorine, chromium, and chromium oxide.

It is preferred that the doped metal oxide is cubic cerium(IV) oxide doped with indium (In), i.e. “In-doped CeO₂”. For example, the doped metal oxide may be 5 wt. % In-doped CeO₂, 10 wt. % In-doped CeO₂, or 15 wt. % In-doped CeO₂.

The metal oxide particles may be of any suitable particle and preferably are below 100 nm. Ideally, they are from 1 nm or smaller to 30 nm in diameter when essentially spherical in morphology or 1 nm or smaller to 30 nm in size as defined by the longest dimension of the particle. Typically, each cubic nanocrystal preferably has a width of from about 1 nm or smaller to about 30 nm, more preferably 1 nm or smaller to 15 nm, more preferably 1 nm or smaller to 13 nm. Most preferably the width of the nanocubes in a given switching layer is 1 nm or greater, preferably 2 nm or greater and most preferably about 8 to 10 nm. It is most preferred that the particles used in a given switching layer are as close to monodisperse as possible as this increases the uniformity in individual 2D and 3D arrays formed by the deposition of the cubic nanocrystals. It is believed that this uniformity results in better multilevel endurance stability of the memory structure and uniformity of the resistive switching parameters of the switching layer (e.g. a high ON/OFF ratio), and thereby better overall performance of the memory device.

It is envisaged that other material layers may be present in the memory units of the present invention in addition to the resistive switching material. These may be inorganic materials and/or organic material layers. It is also envisaged that any given particulate metal oxide layer may further comprise non-metal oxide particulate materials.

The resistive switching material may consist of and preferably does consist of more than a 2D mono-layer of any given metal oxide particle or particle combination. The preferred deposition techniques of the present invention are solution or liquid dispersion based techniques and these will often result in multiple layers of the same particle materials being deposited at each coating or printing step. Typically, each deposition step produces a metal oxide layer with three or more sub-layers. Thus, for example a resistive switching material as defined in the present invention may have been prepared for example from four cumulative depositions from a liquid suspension of metal oxide particles of a singular composition. Each deposition providing three 2D sub-layers of particles one stacked upon the other to provide a uniform three-layer 3D structure, with the final switching layer after four such depositions consisting of twelve 2D layers of particles of the same material as a 3D stack of uniform 2D layers of metal oxide. Therefore, it should be understood that although the resistive switchable material from a materials perspective is a uniform stack of 2D layers, the staged deposition of the switchable layer may result in distinct “coating” layers in addition to the identifiable 2D particle layers. This the final resistive switching material region within a memory unit may exhibit three distinct properties; the first defined by its overall composition and structure (e.g. thickness), the second by the nature and number of distinct “coating” layers and the third by the nature of the individual 2D particle layers or sub-layers. It should be understood that the switching layer may therefore comprise a number of sub-layers of different type that may not be visible under normal analytical techniques (e.g. microscopic) but which may have a positive impact on the performance of the memory device.

Given any desired thickness for the resistive switching material this layered material may comprise any number of 2D particle layers depending on the particle size. Thus, for example the switching layer may comprise 1 to 50 or more, 2D particle layers stacked one upon the other. When there is more than one switching layer present and/or there are other metal oxide particle layers of different composition or form (e.g. particle shape) and function to the switching layer, these may have similar layer sub-structures, with their final 3D layer comprising a plurality of 2D particle layers stacked one upon the other.

The deposition processes used in the present invention along with particle selection results in the formation of these ordered structures. The deposition methods result in a form of self-assembly in each layer, where particles are deposited and under the process conditions align with each other to form ordered 2D layers of particles. It is believed that the that this self-assembly of the un-doped or doped particles and in particular nanocube particles is facilitated by intermolecular forces, for example, van der Waals forces and other forces, and the surfactant-mediated surface hydrophobicity of the liquid medium (e.g. a suitable organic solvent and a suitable surfactant) in which the un-doped or doped nanocubes are dispersed during preparation. As a result, each cube aligns itself relative to other cubes to form a near close packed like array facilitating even and proportional spacing between adjacent nanocubes. The cubic structure in nanometre scale and narrow size dispersion are preferable to form highly coordinated arrays that can be packed closely for data storage. The ultra-small dimension of un-doped and doped nanocubes and intermolecular forces, for example van der Waals, forces between the nanocubes may allow the layers to be flexible and/or when deposited on the appropriate substrates stretchable (for example the layer may follow the curvature of a curved object or expand when the substrate is elastic and is elongated). The distinct geometry of un-doped and doped nanocubes is also believed to be responsible for the enhanced multilevel endurance stability and also excellent non-volatile behaviors yielding a high on/off ratio in the memory devices of the present invention. It is also envisaged in the present invention that 2D layers may have a non-uniform arrangement, packing of the nanocubes and that there may be present localized regions of close packed or near close packed arrays interspersed between regions where there is some level of alignment of the nanocubes but they are not in close packed arrays.

Within a resistive switching material, each coating layer or layer or sub-layer may have the same thickness or have different thicknesses. As indicated above these layer thicknesses will be controlled by and dependent upon the number of deposition steps in the manufacturing process, the particle sizes used and the number of sub-layers deposited at each stage. Generally, particle based layers may have a thickness that is linked to the size of the nano particles used in its manufacture. If the layer is a 2D monolayer, then the thickness will be the dimensions of the nano particle used. Generally, particle based layers may have a thickness of 1 nm or less to 2 μm, preferably 1 nm to 2 μm, and most preferably from 2 nm to 2 μm. Preferably the process is controlled to provide functional layers (comprising multiple 2D particle sub-layers of less thickness) of thickness from 3 nm or less to 500 nm, more preferably 3 nm to 500 nm and most preferably 10 nm to 500 nm, more preferably 20 nm to 400 nm, more preferably 40 nm to 400 nm, more preferably from 50 nm to 300 nm, more preferably from 80 nm to 200 nm, most preferably from 100 nm to 180 nm and these thickness ranges can be altered and controlled by selection of an appropriate manufacturing technology for deposition of metal oxide particles Differing thicknesses of the layers may affect the resistive states of the memory unit.

The memory device in some embodiments of the present invention has high transparency, for example 70% to 80% in the visible range. This is especially the case with the systems based on cerium oxide, which is a wide bang gap material and is transparent to visible light. The transparency of the metal oxides layers is retained or enhanced when organic solvents and certain surfactants are used in the formulation of the metal oxide suspension for the deposition process e.g. toluene as solvent and oleic acid as surfactant, which form a transparent solution or dispersion. This high transparency compares well against glass which is typically around 80%. These properties make the memory units of the present invention potentially well suited for transparent electronics.

Nanocrystals of metal oxides or doped metal oxides, including CeO₂ nanocubes or In-doped CeO₂ nanocubes, can be prepared by methods known in the art. Preferred methods are as described in Younis, A., Chu, D., Mihail, I., and Li, S., “Interface-Engineered Resistive Switching: CeO₂ Nanocubes as High-Performance Memory Cells”, ACS Appl. Mater. Interfaces, 2013, 5, 9429-9434; and in Younis, A., Chu, D., Kaneti, Y. V., and Li, S., “Tuning the surface oxygen concentration of {111} surrounded ceria nanocrystals for enhanced photocatalytic activities”, Nanoscale, 2016, 8, 378 and in Kazumi, et.al, in Advanced Powder Technology, Volume 25, Issue 5, September 2014, Pages 1401-1414, the whole contents of which are hereby incorporated by reference.

Preferred, CeO₂ based nanocubes may be prepared using a hydrothermal process using a cerium precursor in an aqueous environment. Hydrothermal process is generally defined as crystal growth process under high temperature and high pressure water conditions of substances which are insoluble in ordinary temperature and pressure (<100° C., <1 atm). It is considered one of the most effective methods to synthesize morphologically controlled nanoparticles of high purity with high dispersion and narrow size distribution. The crystal growth is performed in an autoclave. The cerium precursor may be a water-soluble cerium(III) salt, e.g. cerium(III) nitrate, cerium(III) chloride or cerium(III) sulfate. In preferred embodiments, the cerium precursor is cerium(III) nitrate. In a typical preparation of CeO₂ nanocubes, an aqueous solution of cerium(III) nitrate is added into an autoclave, and then a mixture of toluene and oleic acid (OLA) is added. Subsequently, tert-butylamine is added into the autoclave under an ambient atmosphere. The sealed autoclave is heated at a temperature in the range of about 100° C. to 250° C., preferably 190° C. to 220° C., more preferably 200° C. to 220° C., for about 10-40 hours, preferably 30-36 hours, and then cooled to room temperature. The upper organic crude layer of the resulting product is centrifuged to separate the CeO₂ nanocubes. The CeO₂ nanocubes may be washed with an organic solvent (e.g. ethanol) and/or deionized water. Washing the nanocubes reduces the amount of absorbed organic material. In-doped CeO₂ nanocubes may be prepared using a similar method as that described above for CeO₂ nanocubes, but incorporating the use of an indium-containing reagent. The indium-containing reagent may be indium nitrate hydrate or indium chloride, and when used in differing amounts, results in In-doped CeO₂ nanocubes having different levels of indium. In a typical preparation, cerium(III) nitrate aqueous solution and indium nitrate hydrate aqueous solution are added into an autoclave, and then a solution of toluene and oleic acid is added. Subsequently, tert-butylamine is added into the autoclave under an ambient atmosphere. The sealed autoclave is heated at a temperature in the range of about 180° C. to 220°, preferably 200° C. to 220° C., for about 30-36 hours and then cooled to room temperature. The upper organic crude layer of the resulting product is centrifuged to separate the In-doped CeO₂ nanocubes. The In-doped CeO₂ nanocubes may be washed with an organic solvent (e.g. ethanol) and/or deionized water. The In-doped CeO₂ nanocubes are dried at elevated temperature (e.g. about 80° C.) for about 24 hours. In some embodiments if desired he product may be calcined and preferably when calcined is calcined in air at about 180° C. for 1 h. The present invention further provides for a resistive-switching memory unit comprising a first electrode, a second electrode and resistive switching material located between the first and second electrodes and wherein the resistive switching material comprises doped and/or undoped calcined particulate metal oxide. It is preferred that the nanocube product is not calcined after synthesis and separation and drying.

The memory structures of the present invention comprising layers of metal oxide particles may be fabricated by forming layers adjacent to the previous layer. Typically, in order to form a layer of self-assembled CeO₂ nanocubes or self-assembled In-doped CeO₂ nanocubes on an electrode, or on a previous layer or a substrate, a stable dispersion is prepared by dispersing the nanocubes in a liquid medium that is capable of dispersing the nanocubes. The liquid medium can be prepared from any suitable liquid, e.g. from a solvent or a mixture of solvents. Advantageously, a stable dispersion can facilitate the self-assembly of the nanocubes. In some embodiments, the liquid medium is an organic solvent or a mixture of organic solvents. The organic solvent may, for example, be toluene, ethanol or n-hexane. In preferred embodiments, the organic solvent is toluene. The stable dispersion may, for example, also comprise a surfactant, e.g. oleic acid. The surfactant may be used to tune the degree of self-assembly of the nanocubes. Typically, the nanocubes are added to an organic solvent and then mixed thoroughly. Mixing and even distribution of nanocubes may be carried out by shaking or, preferably, sonication for a few minutes. In some embodiments, the dispersion is an ink, e.g. a printable ink. In one embodiment, the dispersion can be used by solution processed techniques (e.g., dip coating, spin coating, spray coating, printing) to form the memory structure. Modifications to the rheological, solubility and wettability properties of the dispersion can be made to suit a particular solution processed technique. For example, in inkjet printing, jetting characteristics can be can be adjusted by the addition of a surfactant (e.g. oleic acid) and/or solvent (e.g. toluene, ethanol or n-hexane) to the dispersion. Those skilled in the art will readily envisage other modifications to the dispersion within the spirit and scope of this specification.

There are a range of solution and dispersion based methods for depositing a metal oxide particulate layers onto a substrate for use in a memory device of the present invention. These solution or dispersion processes include such techniques as spin coating, spray coating, dip coating, drop coating, nanoimprint, ink-jet printing, spray printing, intaglio printing, screen printing, flexographic printing, offset printing, stamp printing, gravure printing and aerosol jet.

One way of depositing a particulate metal oxide layer in the present invention is through the drop-coating method. The drop-coating method involves putting one or two drops of a dispersion of undoped or doped nanocubes (typically one drop is equilibrium to about 100 μL) onto an electrode, or onto a previous layer of doped or undoped nanocubes. Residual amount of oleic acid absorbed on the nanocubes facilitates the self-assembly of the nanocubes in the layer. Typically, the layer is allowed to dry naturally and then treated with ultra-violet radiation, for about 1 to 4 hours before the next layer is formed.

Another fabrication method is the use of spin coating techniques to deposit layers of self-assembled metal oxide nanocubes. A small amount of the dispersion is put onto the electrode or previously deposited layer. The substrate is then rotated at high speed in order to spread the coating material by centrifugal force. Rotation is continued while some of the dispersion spins off the edges of the substrate, until the desired thickness of the film is formed by the residual dispersion. Typically, the layer is allowed to dry naturally and then treated with ultra-violet radiation, for about 1 to 4 hours before the next layer is formed. Thin and uniform layers can be produced by spin coating method.

In an alternative fabrication method, inkjet printing techniques may be used to deposit layers of self- assembled metal oxide nanocubes. A certain amount of the dispersion is put into a printing head in an inkjet printer. The dispersion is then deposited through the inkjet nozzle onto the substrate or previous layer. Typically, the layer is allowed to dry naturally and then treated with ultra-violet radiation for about 1 to 4 hours before the next layer is formed. Thin and uniform layers can be produced using inkjet printing method.

With reference to all embodiments of the present invention it is preferred that all of the material layers comprising the resistive switching material and electrodes and any further layers preset are deposited by means of a printing process and most preferably an ink-jet printing process.

When the memory devices of the present invention incorporate other layered materials such as electrodes or other layers that are not particulate in form then other techniques may be used to deposit such layers. Those skilled in the art will readily envisage other methods of depositing these layers within the spirit and scope of this invention. For example, physical vapor deposition (PVD), chemical vapor deposition (CVD), molecular beam epitaxy (MBE), nanoimprint, ink-jet printing, spray printing, intaglio printing, screen printing, flexographic printing, offset printing, stamp printing, gravure printing, aerosol jet, thermal and laser-induced processes. These further layers may be provided through the use of inkjet printing of conductive inks or other materials to provide the required layers of other functionality.

In the memory structures of the present invention, the layers of the memory unit are typically fabricated upon a substrate on which an electrode can be deposited and this is referred to as the bottom electrode. The electrodes may be a conducting or semiconducting material, which generally can be applied from solid or liquid phase by a wide range of physical and chemical means. Conductive and semi conductive materials can be suspended or dissolved to form inks, e.g. based on conductive metals (e.g. silver paste), conductive metal alloys, conductive metal oxides, carbon black, semi conductive metal oxides and conductive polymers (e.g. polyaniline, PEDOT). The electrode may be deposited on the substrate/film by physical and chemical deposition methods or solution processed techniques. The size of the electrode may be any suitable size depending on the intended application. The thickness of the electrode may be in the range from several nanometers to several hundred micrometers.

The memory structures of the present invention may be prepared using a wide range of substrates including glass, plastic, silicon and other materials that provide a suitable surface for depositing a layer of metal oxide. Typically, these substrates are dimensionally stable such that the memory structures are not distorted or stressed during use. The thickness of the substrate may be in any suitable thickness depending on intended purpose. The thickness of the substrate may, for example, be about 25 μm to about 5 mm. Those skilled in the art will readily envisage other suitable substrate materials to deposit the memory structure on within the spirit and scope of this specification.

The memory structures of the present invention may be prepared as flexible memory structures on relatively thin and flexible substrates such as polymeric substrates or flexible glass or metal or composite substrates. In the context of the present invention and under conventional definitions these substrates may be bent in-plane but do not elongate in-plane; they are not able to stretch or deform. They may be flexed in a twisting and/or bending action and it is to be understood that this is not considered to be deformable behavior in the context of the present invention.

In those aspects of the present invention relating to stretchable memory devices the substrate is typically an organic polymeric material which has elastomeric properties or which may be stretched. There are many such materials in the art that are suitable as elastomeric substrates for the present invention. These may include thermoplastic or thermoset substrates. Thermoplastic substrates may include, styrenic block copolymers (TPE-s), thermoplastic olefins (TPE-o), elastomeric alloys (TPE-v or TPV), thermoplastic polyurethanes (TPU)including ester and ether based polyurethanes, thermoplastic copolyester and thermoplastic polyamides. Preferred thermoplastic elastomers include the thermoplastic polyurethanes and especially ether based polyurethanes. Also suitable are various resin based thermoset materials that may be used to provide a variety of substrate forms. Also suitable are stretchable substrates that have elongation and retraction properties by nature of their manufacture as in tightly woven substrates or fabrics for clothing or other applications such as furniture or building products. Also suitable are natural products such as leather. All of these materials may be surface treated to assists with the deposition and maintenance of deposited memory devices in accordance with the present invention.

In those aspects of the present invention relating to deformable substrates the substrate is capable of significant dimensional deformation either during manufacture of the memory device after the particulate metal oxide deposition stages or at any time before its use. One specific dimension is the deposition surface area of the substrate. Thus, in one embodiment a substrate is selected, which may be subject to inelastic expansion such that the size of the deposition surface area is increased once that inelastic expansion is induced. During manufacture of the memory device the substrate is maintained with its pre-expansion dimensions during the deposition of the particulate metal oxide particles and upon completion of that deposition is then subjected to conditions that induce the required inelastic expansion. This expansion has the effect of inducing minor levels of separation of the metal oxide nanocubes from their neighbors within each 2D array in the device. This separation may assist in providing enhanced memory performance.

### BRIEF DESCRIPTION OF THE DRAWINGS

The present invention will be further illustrated with reference to the drawings, in which:

FIG. 1 shows a schematic representation of a resistive-switching memory unit according to the first embodiment of the present invention;

FIG. 2 shows a schematic representation of a resistive-switching memory unit according to the second embodiment of the present invention;

FIG. 3 shows a schematic representation of a resistive-switching memory unit according to the third embodiment of the present invention;

FIG. 4 shows a schematic representation of a resistive-switching memory unit according to the sixth embodiment of the present invention;

FIG. 5 shows a schematic representation of a resistive-switching memory unit according to the eight embodiment of the present invention;

FIG. 6 shows the I-V profile for a resistive-switching memory unit according to the first embodiment of the present invention under current compliance operation;

FIG. 7 shows the stability of the device in FIG. 6, under 1000 ON/OFF cycles switched at 4V;

FIG. 8 shows the structure and stretching of a resistive-switching memory unit according to the sixth embodiment of the present invention;

FIG. 9 shows the I-V and cycle stability for the as manufactured device of FIGS. 8; and

FIG. 10 shows the I-V and cycle stability for the manufactured device of FIG. 8 on its first elongation;

FIG. 11 shows the I-V and cycle stability for the manufactured device of FIG. 8 on its fifth relaxation;

FIG. 12 shows on/off ratios for the device as manufactured in FIG. 8 at each stretch and relax cycle; and

FIG. 13 shows the I-V profile for a stretchable device according to the sixth embodiment of the present invention;

FIG. 14 shows the I-V profile for the device of FIG. 13 at different elongations;

FIG. 15 shows the structure and stretching of a resistive-switching memory unit as used in Examples 6 and 7;

FIG. 16 shows I-V profile and endurance performance for the ninth stretch cycle of Example 6 (the results of the 5^{th} IV-Cycle and then subsequent 1000 cycle endurance test are shown);

FIG. 17 shows I-V profile and endurance performance for the ninth relax cycle of Example 6 (the results of the 5^{th} IV-Cycle and then subsequent 1000 cycle endurance test are shown);

FIG. 18 shows the results of three IV-Cycles and then subsequent 1000 cycle endurance test of a pristine device of Example 7; and

FIG. 19 shows the I-V profile and endurance for a device of Example 7 after 100 stretch/relax cycles (the results of three IV-Cycles and then subsequent 1000 cycle endurance test of a device that has been stretched and relaxed 100 times are shown).

### DETAILED DESCRIPTION OF DRAWINGS

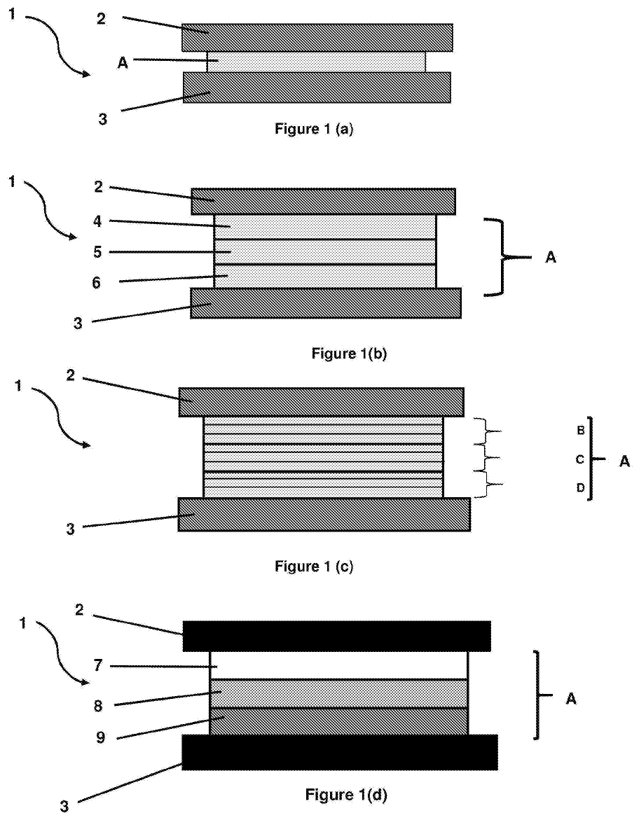

With reference to FIG. 1 there is shown an example of the first embodiment of the present invention. In FIG. 1(a) a resistive-switching memory unit (1) consists of a top electrode (2) and a bottom electrode (3) and sandwiched between these electrodes is a region of resistive switching material (A). In this FIG. 1(a) the resistive switching material (A) is shown as a single 2D layer made from a single type of doped metal oxide in particulate form. In a preferred arrangement, this particle form is cubic and preferably crystalline cubic in nature. A preferred example is where this resistive switching material (A) consists of indium doped cerium (IV) oxide. In FIG. 1(b) is shown an arrangement where the resistive switching material (A) has been formed through a single liquid coating step during its manufacture. The single coating mixture comprises nano particulate doped metal oxide and after a single coating this mixture provides a stack of three (in this example) 2D arrays of nano particles (4,5 and 6), which have self-assembled one on top of the other to form a 3D stacked arrangement as the resistive switching material (A) sandwiched between top (2) and bottom (3) electrodes.

With reference to FIG. 1(c) there is shown a resistive-switching memory unit (1), where the resistive switching material (A) has been prepared in a similar fashion to that shown in FIG. 1(b) but via three coating stages. Each coating stage (B, C and D) provides a three-layer stack of 2D nano particulate arrays (4,5 and 6 as illustrated in FIG. 1(b)), that together make up the resistive switching material (A), which in this figure now comprises three coating layers (B, C and D) and 12 2D nano particulate arrays that have self-assembled during the manufacture of and forming of the resistive switching material (A). In FIG. 1(c) each of the 12 layers is of the same composition and consist of the same doped metal oxide. With reference to FIG. 1(d) there is shown a further arrangement, where the resistive switching material (A) now consists of three chemically or structurally distinct layers (7, 8, and 9). Each of these layers is manufactured from a doped particulate metal oxide. Each layer is manufactured from a different doped metal oxide or a metal oxide of nominally the same composition, but which may be in a different form e.g. morphology, or size, or shape. The whole of the resistive switching material (A) consists of doped particulate metal oxide and preferably nano particulate metal oxide and most preferably cubic form particulate and crystalline metal oxide. The individual layers (7, 8, and 9) may be 2D monolayers of nano particles as illustrated in FIG. 1(a) or they may comprise a stack of 2D monolayers as described in FIG. 1(d) from a single coating stage or they each may be produced by multiple coating stages as illustrated in FIG. 1(c). It should be understood that each layer of doped metal oxide may comprise a mixture of doped metal oxides of different levels of doping and/or of different types of dopant and/or different type of base metal oxide.

In this first embodiment the memory unit may have a resistive switching material containing a 2D array of nanocubes of a first doped metal oxide and a further one or more 2D arrays of nanocubes of a second or further doped metal oxide. In one embodiment the dopant of the second doped metal oxide is different from that of the first doped metal oxide. In a further embodiment the dopant of the second doped metal oxide is the same as the dopant of the first metal oxide but the metal oxide of the second doped metal oxide is different from that of the first doped metal oxide. In a further embodiment the dopant and metal oxide of the second doped metal oxide are both identical to the first doped metal oxide, but the levels of dopant are different from the first doped metal oxide. In a preferred embodiment the first doped metal oxide is indium doped cerium (IV) oxide and the second doped metal oxide is indium doped metal oxide with a higher level of indium doping than the first doped metal oxide.

In this embodiment, it will be immediately apparent that a wide variety of arrangements are possible depending on the composition of the deposition solutions used during manufacture of the resistive switching material (A) and the number and variety of materials used for each coating and layer. A wide variety of memory units (1) can be manufactured using this approach. Complex memory devices may therefore be manufactured from various arrangements of memory units (1), which are either all identical and stacked or arranged in arrays or which may take the form of more complex and varied stacking and array formations depending on the required function and performance of the memory device.

It should be understood that the memory units as described in the first embodiment may be used with memory units as described in other embodiments of the present invention to prepare complex and functionally varied memory devices. In particular memory units of the first embodiment may be prepared as flexible, or stretchable or deformable memory devise as herein described.

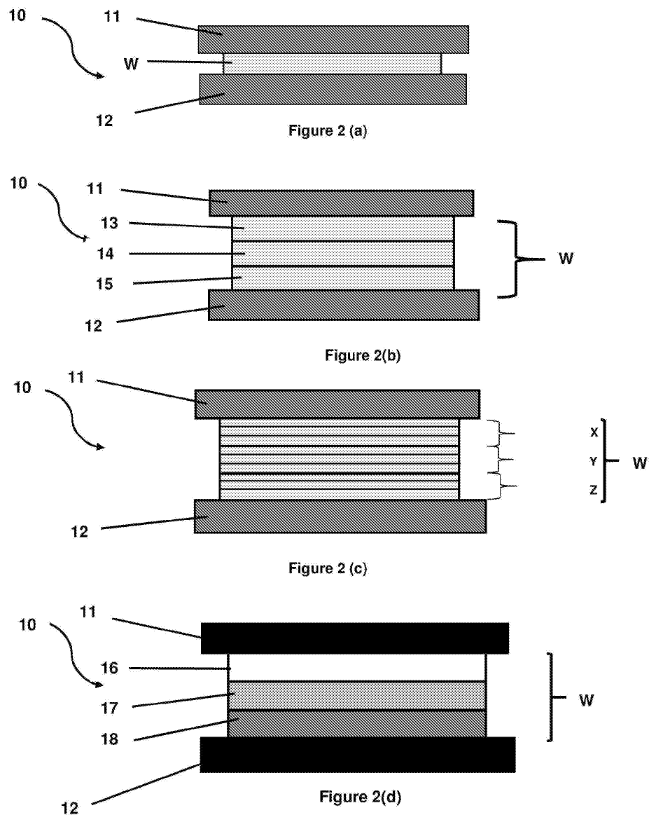

With reference to FIG. 2, there is shown an example of the second embodiment of the present invention. FIGS. 2(a) to 2(d) show structurally identical arrangements to those described in FIGS. 1(a) to 1(d). There are top electrodes (11), bottom electrodes (12) and resistive switching material (W) along with individual 2D monolayers (13, 14 and 15), coating layers (X, Y and Z) and the option for layering using layers of different composition (16, 17 and 18). but with different composition and/or form. The key distinction is that in the first embodiment all of the particulate nano particles are doped metal oxides, whereas in the second embodiment undoped and doped metal oxides may be present with the proviso that at least one layer within the resistive switching material (W) is prepared from a mixture of doped and undoped metal oxide nano particles and preferably nanocube metal oxide. Preferably, crystalline nanocube metal oxide. Other layers present in addition to this layer may be undoped oxide or doped oxide layers of particles, preferably nanocube particles. Thus, in one arrangement for example a first layer could be undoped cerium (IV) oxide nanocubes, upon which has been deposited a mixture of indium doped and undoped cerium (IV) oxide nanocubes. Ina further example the arrangement could use a doped cerium (IV) oxide nano cube material for the first layer or a completely different undoped or doped metal oxide.

The memory units as described in the second embodiment may be used with memory units as described in other embodiments of the present invention to prepare complex and functionally varied memory devices. In particular memory units of the second embodiment may be prepared as flexible, or stretchable or deformable memory devise as herein described.

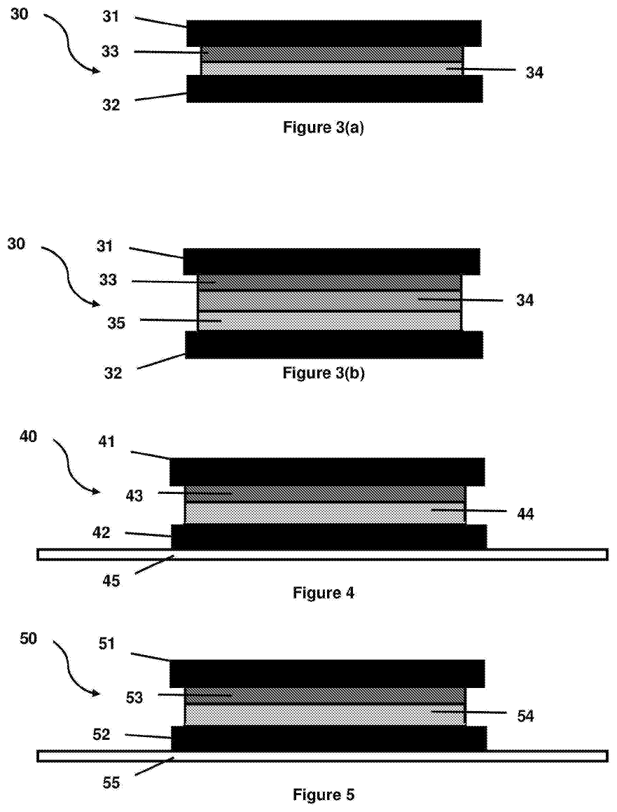

With reference to FIG. 3, there is shown an example of a third embodiment of the present invention, which uses a hybrid resistive switching material (33 and 34). By hybrid in the context of the present invention is meant a resistive switching material, which comprises multiple-layers of material and in which the layers have been prepared using different deposition techniques, one of which is a solution or dispersion based deposition technique. This is first illustrated in FIG. 3(a), which shows a top electrode (31) and a bottom electrode (32) and located between these electrodes is a hybrid resistive switching material consisting of two layers (33,34). Layer (33) may comprise metal oxide material that has been deposited using conventional semiconductor manufacturing techniques (e.g. sputtering, CVD, ALD, PVD and PLD) and layer (34) has been deposited from a solution/dispersion of metal oxide particles and preferably metal oxide nano particles. The composition of both layers (33) and (34) may be chemically identical e.g. they may both be the same metal oxide, but they will have different morphologies; this layer (33) may be continuous and amorphous whereas (34) could be a 2D array of nanocubes. These layers could also be of different compositions. With reference to FIG. 3(b) there is shown a further arrangement where there is a third layer (35) present. This layer could be similar to layer (33) in terms of its method of deposition or it could be similar to layer (34) in its method of deposition. It could be identical to layer (33). In a further variance on the arrangement of FIG. 3(b) layers (33) and (35) maybe solution/dispersion deposited 2D layers of nanocubes and layer (34) could be a uniform and amorphous layer deposited using conventional semiconductor manufacturing techniques.

The memory units as described in the third embodiment may be used with memory units as described in other embodiments of the present invention to prepare complex and functionally varied memory devices. In particular memory units of the third embodiment may be prepared as flexible, or stretchable or deformable memory devise as herein described.

With reference to FIG. 4 by way of example is illustrated the sixth embodiment of the present invention. It has been surprisingly found that when memory units are manufactured using nano particle suspension/dispersion techniques and most preferably when the nano particles used are cubic nano crystals, then the memory unit may be manufactured upon an elastomeric substrate to provide a stretchable resistive RAM memory unit. The elastomeric substrate may be stretched, stretching the memory unit and the memory unit will still operate in both the stretched and post stretching relaxed states. In FIG. 4, there are shown a top electrode (41), which is thin and deposited using conventional deposition techniques, a bottom electrode (42), which is thin and screen printed. Located between these electrodes (41,42) are drop coated layers (43, 44) forming a resistive switching material of nano cubic metal oxide. Layer (43) may for example be a 2D or 3D array of indium doped cerium (IV) oxide nanocubes and layer (44) may for example be a 2D or 3D array of undoped cerium (IV) oxide nanocubes. The electrodes (41, 42) and layered restive switching material (43,44) combine to form memory unit (40), which is supported upon and attached to an elastomeric substrate (45). The whole device may be elastically deformed.

The memory units as described in the sixth embodiment may be used with memory units as described in other embodiments of the present invention to prepare complex and functionally varied memory devices. In particular memory units of the first, second and third embodiment may be prepared as stretchable memory devices as herein described. The resistive switching material in the sixth embodiment may be manufactured using any particulate resistive switching metal oxide. This includes doped and undoped particulate metal oxides and in particular nano cube metal oxides and especially such oxides that are capable of self-assembly to form 2D layers within the structure of the resistive switching material.

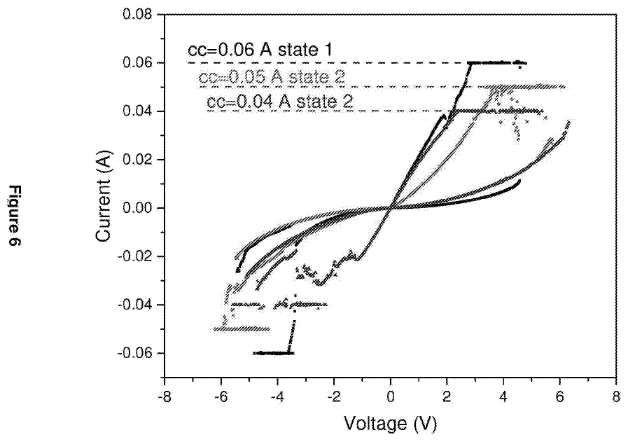

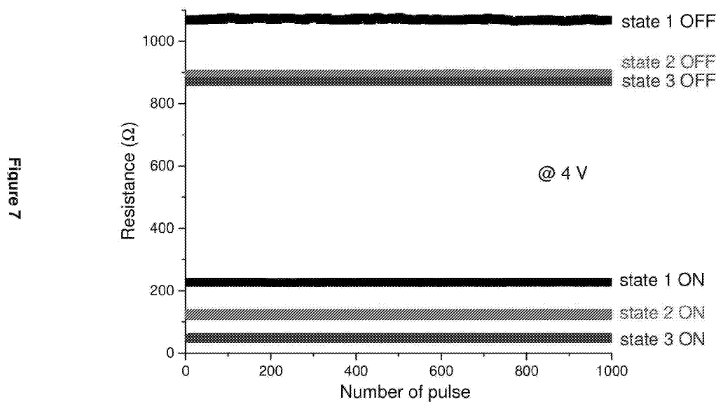

With reference to FIG. 5 by way of example is illustrated the eighth embodiment of the present invention. It has been surprisingly found that when memory units are manufactured using nano particle suspension/dispersion techniques and most preferably when the nano particles used are cubic nano crystals, then the memory unit may be manufactured upon a deformable substrate to provide a deformable resistive RAM memory unit. In contrast with embodiment six the substrate is deformable but is not elastically deformable. With reference to FIG. 5 all the features apart from the nature of the substrate (55) are identical. The memory units as described in the eighth embodiment may be used with memory units as described in other embodiments of the present invention to prepare complex and functionally varied memory devices. In particular memory units of the first, second and third embodiment may be prepared as deformable memory devices as herein described. The resistive switching material in the eighth embodiment may be manufactured using any particulate resistive switching metal oxide. This includes doped and undoped particulate metal oxides and in particular nano cube metal oxides and especially such oxides that are capable of self-assembly to form 2D layers within the structure of the resistive switching material.

The present invention will now be further illustrated by means of the following procedures and examples.

### A. Device Fabrication Processes

### Bottom Electrode Deposition:

1. The substrate material used was typically Si/PET/Glass or other materials such as elastomeric materials and normally the dimensions of substrate are 2-2.5 cm (length)×1.5 cm (width).

2. At the first step electrode material e.g. metal (Aᵤ) is deposited on a substrate to provide a conductive substrate. A sputter coater (Leica sputter coater) was used to deposit bottom electrode at 40 mA for 3-4 minutes.

3. The electrode sputtered sample was then treated under a UV light source for at least 30 minutes prior to deposition of the metal oxide film.

### Spin Coating:

4. A coating suspension solution is prepared using solvent and surfactants and it is spin coated on the substrate with bottom electrode to fabricate thin films of metal oxide nanoparticles.

5. Typically, 10 μl solution is spin coated over substrate with spin coating speed of 500 RPM for 40 seconds.

6. Step 5 may be repeated up to 9 times or more to provide the desired layer thickness for the nanocube film.

7. After step 6, the sample was treated under UV light source for at least 2 hours in order to remove all solvent and organics from the layered film.

8. After UV treatment steps 5-7 were repeated to add a further alternative material layer. The UV treatment step is therefore carried out after each film deposition.

9. Once, all the desired layers are deposited, the sample was subjected to UV light source for at least 3-4 hours to make sure that the film is reasonably free from any solvents and organics or impurities.

### Ink-Jet Printing

10. The inkjet printer used was a Fujifilm DMP ink-jet printer. Typically, 1-1.5 ml of nano-cube suspension solution was used as the ink to fill the cartridge of the printer.

11. The cartridge was mounted in the printer and allowed to stabilize for 10 minutes.

12. After 10 minutes' notice is made of the drop watcher to observe the drops coming from all of the nozzles of printing head.

13. The pulse width, shape, and voltage to control the drops size/movement was tuned to ensure there are no residues associated with the drops.

14. Once these settings have been determined those nozzles which are dispersing ink are selected and all other nozzles are blocked.

15. Then a printing area on the substrate (normally 20-25 mm) in length and 10-15 mm in width was selected.

16. The print origin is selected if multi-layers need to be deposited and normally deposition of multilayers is required to provide the desired film thickness.

17. After deposition of every two layers the deposited layers are exposed to 15 minutes of UV treatment to remove all solvent and organics.

18. Once, the desired film has been fabricated with the desired thickness, the film was then subjected to UV light source for 3-4 hours to fully dry and to fully remove solvent and organics.

19. This film is ready for top electrode deposition for characterizations.

### Top Electrode Deposition:

20. In order to deposit the top electrode a metal shadow mask is used to deposit circular shaped top electrode (Au/Ag) via Leica sputter coater using same conditions described in steps 2-3. The size of electrodes varies from 50 μm to 250 μm.

21. The bottom gold electrode typically has a thickness of around 50 nm. The top electrode typically has a thickness of around 70 nm. In relation to the bottom electrode this can be made from a range of different materials including, but not limited to: platinum, iridium, silver, gold or any combination thereof.

After deposition of the top electrode the device is ready to conduct testing measurements.

### B. Testing Procedures

### IV Curves

1. For basic memory testing a voltage sweep mode is first run to extract current voltage measurements. Once, a discrete transition from a conductive state to another conductive state (could be low or high), depending upon current variation as compared to previous state, is observed this measurement is recorded as a conventional voltage sweep IV curve. (Test-1, T-1)

### Endurance Testing

2. For the endurance test, the voltages in T-1 are considered and where jumps or declines in current level of the sample are observed one more sweep is carried out to achieve the first transition point. After achieving this transition point constant voltage pulses are imposed (relatively small voltage to set potential) (0.1-0.5V) and width (0.01 s to 0.0001 s), for a number of cycles (e.g. 1000 or so). In conjunction to those pulses, the current level of the sample (device) is recorded. This current value Vs. cycles (number of pulses) will provide an endurance plot of a single state [test-2, T-2].

3. After T-2 is completed one more sweep measurement is run to determine another current transition state which should be different from the state observed in T-2. The endurance measurements are carried out at this second current transition as described in 2. This provides a further current level Vs. cycles for a said number of cycles. [Test-3, T-3]

4. Steps 2 and 3 are repeated if more than two current transitions were observed in voltage sweep measurements (Test-1).

5. After measuring at all current levels for a given number of cycles a plot is made of all the states (current/resistance levels by calculating resistance using ohm's law) Vs. number of cycles and this plot will provide a complete detailed endurance test of a given device for a said number of cycles.

### Retention Testing

6. To conduct retention test, the same sequence, as described in points 1-4 above is run but the only difference is that the experiment is run in a way such that only one constant read puise (with defined width) is used and the sample's response is recorded for a period of time (e.g. 4000 seconds). [test-4, T-4]

7. After having all the current/resistance levels for a given period of time the date is re-plotted in a single graph to show that the device can sustain all states for a given period of time.

Note: The purpose of endurance and retention tests are to observe sample's response in stress atmosphere. By imposing different number of pulses its fatigue test (endurance) is determined and by imposing a constant pulse for a longer period its retention (ability to sustain its data or information for longer time) is determined.

### EXAMPLE 1

All starting materials were purchased from Sigma and used without further purification. 15 mL of 16.7 mmol l⁻¹ cerium(III) nitrate hexahydrate aqueous solution (0.10 g cerium(III) nitrate hexahydrate) and indium nitrate hydrate aqueous solution were added into a 50 mL autoclave, and then a 15 mL mixed solution of toluene and oleic acid (OLA, 0.6 mL; OLA:Ce 8:1 mol/mol) was added. Subsequently, tert-butylamine (0.15 mL) was added into the autoclave under an ambient atmosphere. The sealed autoclave was heated at 200° C. for 36 h and then cooled to room temperature. The resulting product was isolated by centrifugation (about 4-6 min at 16,000 RPM) and washed three times with ethanol and deionized water, and then dried at 80° C. for 24 h. Resulting in a solid solution of 5 wt. % In-doped CeO₂ (the size of nanocubes varied from 2-13 nm; most of the nanocubes were about 8-10 nm). The preparation of 10 wt. % In-doped CeO₂ nanocubes and 15 wt. % In-doped CeO₂ nanocubes was carried out using the same procedure described above with suitable weight percentage ratios of cerium(III) nitrate and indium nitrate hydrate.

### EXAMPLE 2

Nanocubes were prepared as described in Example 1, and were added to a solution of oleic acid in toluene. The resulting dispersion was sonicated for about 5 min to ensure even dispersion of nanocubes in toluene.

The dispersion was drop-coated a number of times onto a substrate with bottom electrode to obtain self-assembled doped CeO₂ nanocubes based film. The film was treated with ultraviolet radiation for 1 h after every drop-coating to eliminate all organics/extra OLA. The film was finally thermally annealed at 200° C. for 2 h under vacuum. A small area of the electrode (gold, Au) with round patterning and size of about 250 μm diameter was sputtered through a shadow mask to complete the fabrication process.

This sample was tested and found to exhibit a voltage sensitive High Resistive State (HRS) and Low Resistive State (LRS). These states were stable and could be switched for over 1000 pulses.

### EXAMPLE 3

Nanocubes of 5 wt. % indium doped Cerium (IV) oxide were prepared as described in Example 1, and were added to a solution of oleic acid (3 Vol % based in solvent volume) in toluene as solvent. The resulting dispersion was sonicated for about 5 min to ensure even dispersion of nanocubes in the toluene. The final dispersion contained 1 mg of nanocubes per 5 ml.

The dispersion was spin-coated at room temperature at 500 rpm a number of times onto a silicon substrate with gold bottom electrode to obtain a self-assembled doped CeO₂ nanocubes based film (the electrode was deposited as described above for “Bottom Electrode Fabrication”). This was achieved by applying ten 20 ul drops to form a layer on spin-coating. This coating was then treated with ultraviolet radiation for 1 h to eliminate all organics/extra OLA. This drop spin-coated deposition and UV drying was repeated a further eight times to provide a resistive switch material with eight coated layers. The final film was placed under UV light for 3 hours to remove all excess organic materials. A small area of the electrode (gold, Au) with round patterning and size of about 250 μm diameter was sputtered through a shadow mask to complete the fabrication process.

The resulting memory unit which consisted solely of indium doped Cerium (IV) oxide was found to have 3 resistive states when tested under controlled current compliance conditions.

The memory unit was tested with a Keysight B2902A source meter equipped with a probe station after device fabrication. The current compliance (CC) was set from the test software before I-V measurements were made. The current compliance setting prevents the unit device from breaking down. i.e. the voltage automatically stops increasing at the point that the current reaches CC. Thus, for a current compliance (CC) of 40 mA the current increases up to this CC level and then stops increasing; at this point resistance state (R1) will be set within the device. The device then can be reset using an appropriate reset voltage level. Then if the CC level is reset at for example to 60mA this will allow to increase the current level of the device up to this value and stops increasing to prevent breakdown of the device to achieve a further resistance state (R2) is set in the device. In the memory device specific voltages and current can therefore be set to achieve a specific resistance state; when the voltage and more specifically the current compliance are changed then different resistance states can be achieved. Thus the device produced in this example may have various resistance states induced using this current compliance approach.

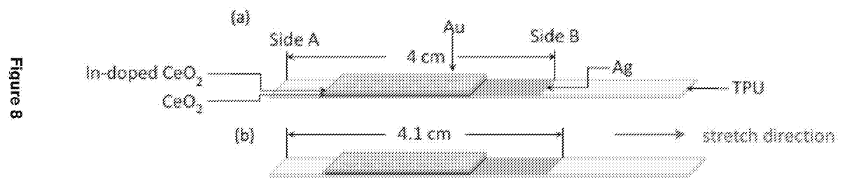

FIG. 6 shows the I-V curves for this device tested at three different current compliances. This shows that three different ON/OFF states could be induced through current compliance.

FIG. 7 shows that all of these ON/OFF resistive states could be switched over at least 1000 cycles showing a high degree of stability for these resistive states in the device.

### EXAMPLE 4

A stretchable resistive switching memory unit was manufactured and tested as follows:

CeO₂ and In-doped CeO₂ nanocubes and their dispersions were prepared by the general method of Examples 1 and 2 and as described in Example 3.

The elastomer substrate used for deposition was a highly elastic thermoplastic polyurethane film supplied by Bayer® as PLATILON® U073. This material had a Shore A hardness of 87 and a tensile strain at break of 650%. This material is an ether based polyurethane.

A sliver bottom electrode was deposited onto this elastomeric substrate by screen printing using DuPont 5064H silver conductor, which is a solvent based silver powder ink with resin binder.

Alternate layers of CeO₂ and In-doped CeO₂ were deposited onto the bottom electrode by “drop coating” using one droplet of 20 ul ink. This provided alternating paired switching layers. Their thickness was around 100 nm.

To complete the device gold top electrodes of diameter 200 um were prepared by sputtering with a shadow mask.

This device was then to a metal plate for I-V testing. This arrangement is shown in FIG. 7. Sides A and B Side were fixed on the metal plate during original and relax states. Side B was elongated 1 mm for the stretchable state along the direction indicated by the red arrow. The strain is estimated by AL/L=0.025 (2.5%), where L is the original length between Side A and Side B, AL is the length of elongation. The device was subsequently measured for I-V performance for five “stretch-relax” cycles.

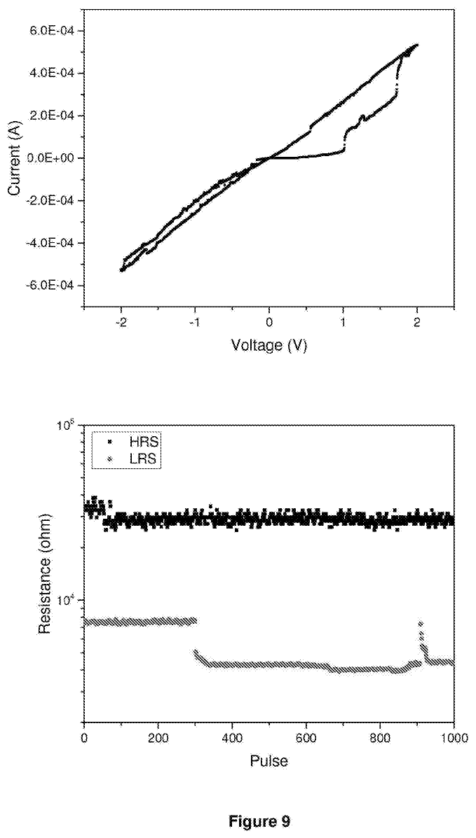

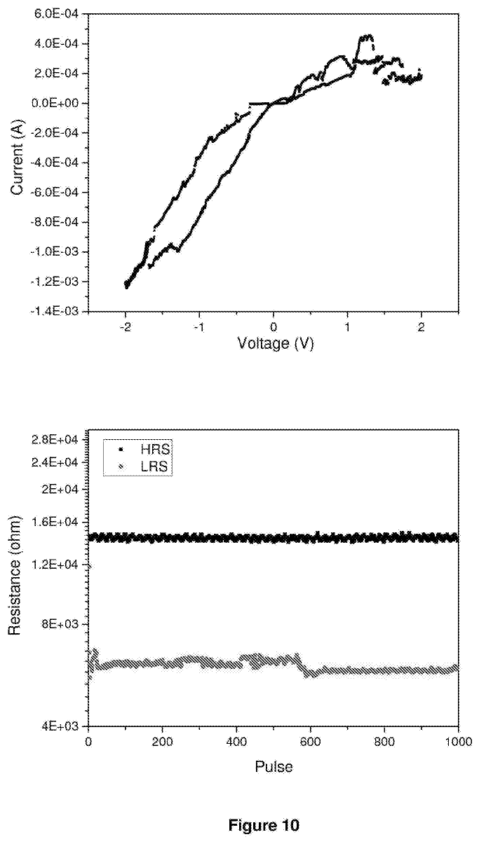

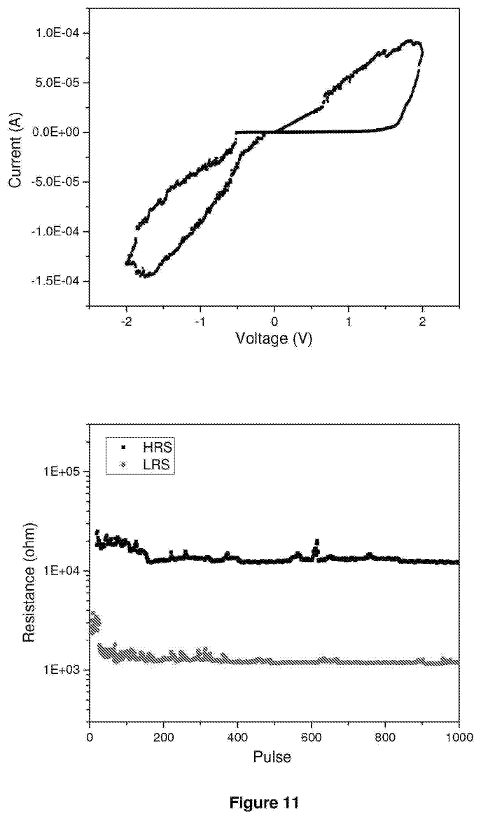

The stretch performance over five stretch cycles in illustrated in FIGS. 9, 10, 11 and 12. FIG. 9 shows the I-V profile and the stability performance for the has manufactured device. FIG. 10, shows the I-V profile and stability performance for the device as first stretched. FIG. 11 shows the I-V profile and the stability performance for the device upon its fifth stretch and relaxation. These figures show that the switchable resistive states of the device remain intact upon repeated stretching and relaxation and that at each stage the switching properties are highly stable after 1000 switching cycles.

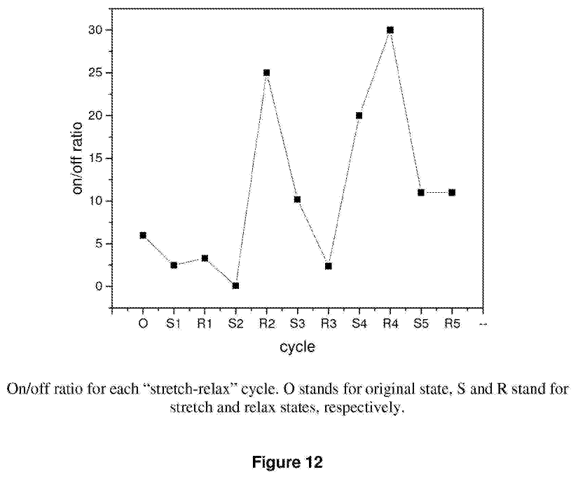

FIG. 12 shows the on/off performance through the stretching and relaxation cycles and whilst this does fluctuate it is stable enough for a usable memory device.

This stretchable device switches at relatively low voltage of up to 2V.

### EXAMPLE 5

A stretchable device was prepared according to the general method described in Example 4, but with the deposition of a further doped metal oxide layer of 5 wt. % indium doped Cerium (IV) oxide to provide a resistive switching material consisting of a paired switching layer of 5 wt. % indium doped Cerium (IV) oxide upon undoped Cerium (IV) oxide. In Example 4 the device was elongated to the same extent during each stretch and relaxation cycle. In this example the device was elongated and relaxed to different levels of stretch. The device was tested at 0, 0.02, and 0.04 strain.

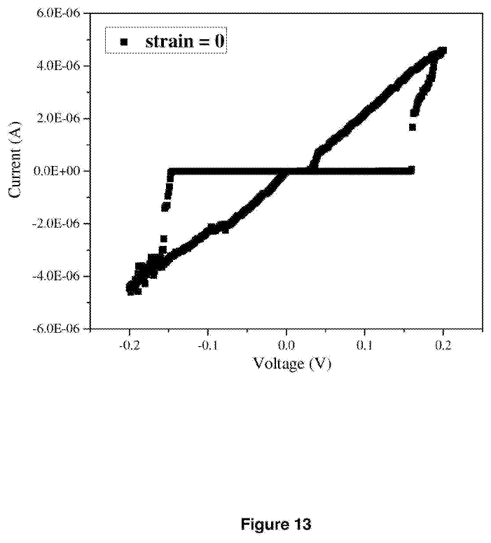

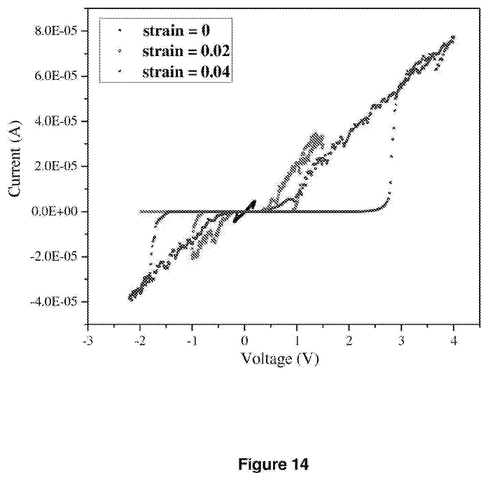

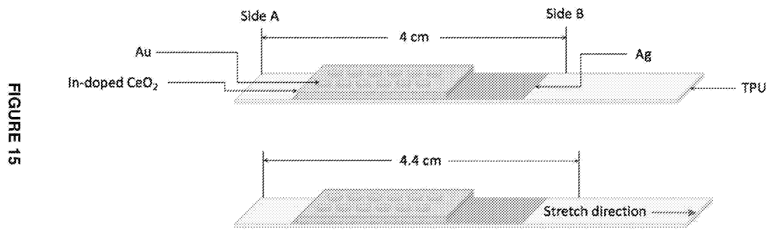

The I-V profiles were measured at each elongation and these are shown in FIGS. 13 and 14.

In FIG. 13, it can be seen that at zero strain (as fabricated) the device has an extremely low switch voltage of about 0.2 V. FIG. 14 shows that this increases as the device is elongated but that the device is still operable at 0.04 strain.

### EXAMPLE 6

A stretchable resistive switching memory unit was manufactured and tested as follows:

In-doped CeO2 nanocubes and their dispersions were prepared by the general method of Examples 1. No additional oleic acid was added to the nanocubes once the synthesis steps described in Example 1 were complete.

The elastomer substrate used for deposition was a highly elastic thermoplastic polyurethane film supplied by Bayer® as PLATILON® U073. This material had a Shore A hardness of 87 and a tensile strain at break of 650%. This material is an ether based polyurethane.

A sliver bottom electrode was deposited onto this elastomeric substrate by screen printing using DuPont 5064H silver conductor, which is a solvent based silver powder ink with resin binder.

A single layer of In-doped CeO2 were deposited onto the bottom electrode by “drop coating” using two droplets of 20 ul In-doped CeO2 ink. A drying time of 1 hour was allowed between droplets. The film was not treated with ultraviolet radiation post deposition.

To complete the device gold top electrodes of diameter 200 um were prepared by sputtering with a shadow mask.

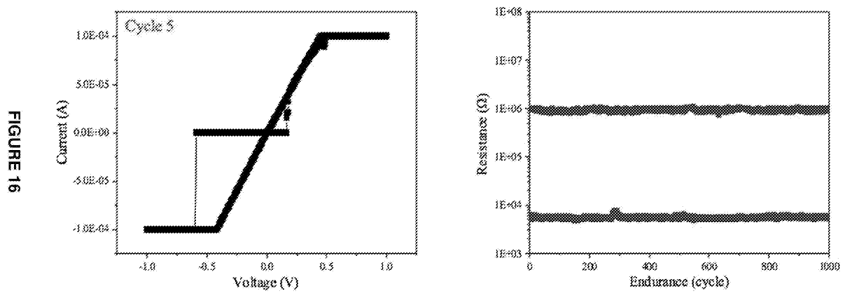

Example 6 was tested in a lateral configuration utilising the coplanar electrode structure, in this configuration, two top electrodes are used for testing rather than a typical top and bottom electrode pairing. The sample was conventionally tested by generating IV curves, additional Endurance testing was conducted at different elongations of the device. The device of Example 6 was attached to a plate for I-V testing. This arrangement is shown in FIG. 15. Sides A and B Side were fixed on the glass plate during original and relax states. Side B was elongated 4 mm for the stretchable state along the direction indicated by the red arrow. The strain is estimated by ΔL/L=0.1 (10%), where L is the original length between Side A and Side B, AL is the length of elongation. The device was subsequently measured for I-V performance and endurance for each stage of a “stretch-relax” test.

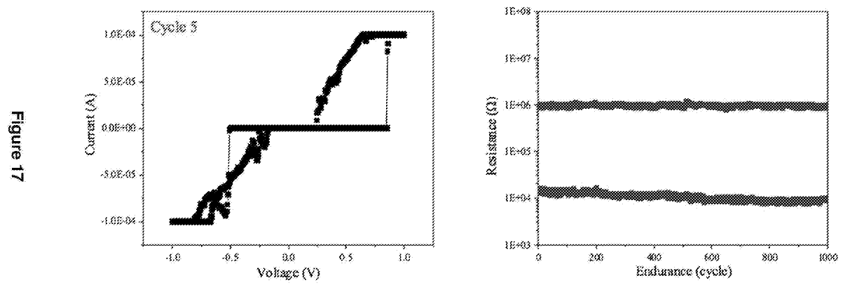

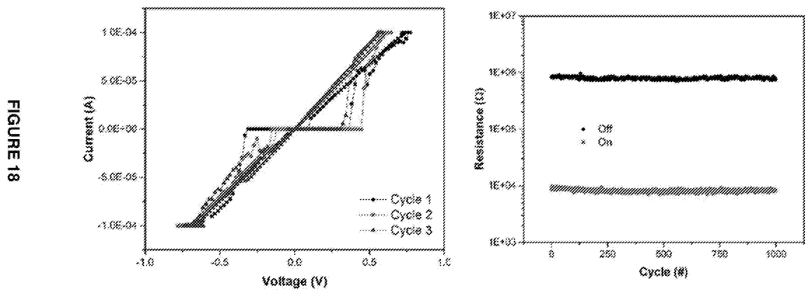

The stretch performance over five stretch cycles in illustrated in FIGS. 15, 16 & 17. shows the I-V profile and endurance performance for the as manufactured device. FIG. 16, shows the I-V profile and stability performance for the device at the ninth stretch cycle; the figure shows the results of the 5^{th} IV-Cycle and then subsequent 1000 cycle endurance test. FIG. 17 shows the I-V profile and the stability performance for the device upon its ninth relaxation; the figure shows the results of the 5^{th} IV-Cycle and then subsequent 1000 cycle endurance test. These figures show that the switchable resistive states of the device remain intact upon repeated stretching and relaxation and that at each stage the switching properties are highly stable after 1000 switching cycles.

### EXAMPLE 7

A stretchable resistive switching memory unit was manufactured as described in Example 6. Example 7 was tested in the same lateral configuration as described for Example 6.

Using the same testing approach in Example 6, Example 7 was stretched and relaxed 100 times over a variety of elongations between 1% to 10%. This test was designed to simulate the use of a deformable memory device in applications that require flexibility for operation.

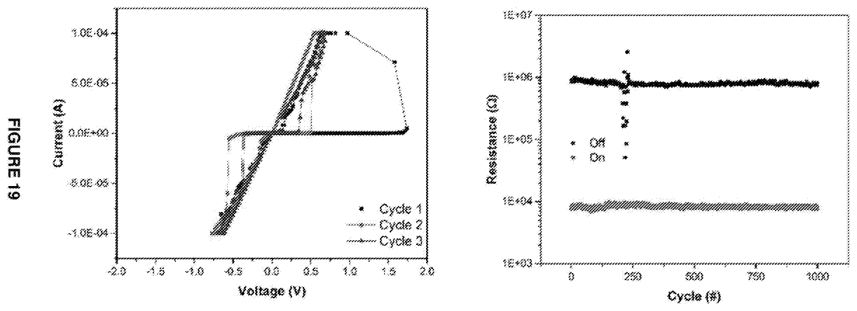

FIG. 18, shows the I-V profile and stability performance for the device prior to testing. FIG. 19 shows the I-V profile and the stability performance for the device upon its final relaxation after being stretched and relaxed 100 times. These figures show that the switchable resistive states of the device remain intact upon repeated stretching and relaxation and that at each stage the switching properties are still stable after 1000 switching cycles.

This testing shows the on/off ratio performance after 100 cycles of stretching and relaxation is stable enough for a usable memory device. Furthermore, the testing of Example 7 shows that the switchable resistive states of the device remain stable upon 100 stretching and relaxation cycles and that at each stage the switching properties are still stable after 1000 switching cycles

All of the features disclosed in this specification for each and every embodiment (including any accompanying claims, abstract and drawings), and/or all of the steps of any method or process so disclosed, may be combined in any combination, except combinations where at least some of such features and/or steps are mutually exclusive.

Throughout the description and claims of this specification, the words “comprise” and “contain” and variations of the words, for example “comprising” and “comprises”, means “including but not limited to”, and is not intended to (and does not) exclude other components, integers or steps.

Throughout the description and claims of this specification, the singular encompasses the plural unless the context otherwise requires. In particular, where the indefinite article is used, the specification is to be understood as contemplating plurality as well as singularity, unless the context requires otherwise. Features, integers, characteristics, compounds described in conjunction with a particular aspect, embodiment or example of the invention are to be understood to be applicable to any other aspect, embodiment or example described herein unless incompatible therewith. Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

1. A resistive-switching memory unit comprising a first electrode, a second electrode and resistive switching material located between the first and second electrodes and wherein the resistive switching material comprises doped particulate metal oxide.

2. The resistive-switching memory unit as claimed in claim 1, wherein the resistive switching material comprises doped particulate metal oxide and undoped particulate metal oxide.

3. The resistive-switching memory unit as claimed in claim 1, wherein the resistive switching material comprises a mixture of the doped particulate metal oxide and undoped particulate metal oxide, or at least one layer of the doped particulate metal oxide and at least one layer of the non-particulate metal oxide.

4. The resistive-switching memory unit as claimed in claim 1, wherein the resistive-switching memory unit has at least one low (LRS) and one high (HRS) resistance state and exhibits an HRS/LRS resistance ratio of 10⁵ or greater.

5. The resistive-switching memory unit as claimed in claim 1, wherein the resistive-switching memory unit has a switch voltage of 2 volts or less.

6. A stretchable or deformable memory device which comprises a resistive-switching memory unit according to claim 1 the unit is attached to and supported by an elastomeric or deformable substrate.

7. A method for manufacturing a stretchable or deformable memory device according to claim 6, which method comprises depositing the first electrode upon the elastomeric or deformable substrate, depositing the resistive switching material upon the first electrode and depositing the second electrode upon the resistive switching material.

8. (canceled)

9. (canceled)

10. The resistive-switching memory unit as claimed in claim 1, wherein the resistive switching material comprises one or more alternating paired switching layers.

11. The resistive-switching memory unit as claimed in claim 1, wherein the metal oxide is in the form of a crystalline particle or has as a cubic morphology.

12. (canceled)

13. The resistive-switching memory unit as claimed in claim 1, wherein the metal oxide is cerium oxide.

14. The resistive-switching memory unit as claimed in claim 1, wherein the doped metal oxide that has more oxygen vacancies than the metal oxide or valency of the dopant metal ion is less than the valency of metal in the core metal oxide.

15. (canceled)

16. The resistive-switching memory unit as claimed in claim 1, wherein the dopant is one or more of: Indium (In); cobalt (Co); gadolinium (Gd); ytterbium (Yb); or samarium (Sm).

17. The resistive-switching memory unit as claimed in claim 1, wherein the doped particulate metal oxides are in the form of metal oxide nanocubes.

18. The resistive-switching memory unit as claimed in claim 1, wherein each single metal oxide particle has a width in the range of from about 2 nm to about 20 nm.

19. The resistive-switching memory unit as claimed in claim 1, wherein the memory structure comprises a first resistive state and a second resistive state and the first the resistive state is higher than the second resistive state, and wherein the structures resistive state may be changed between first and second resistive states in response to an electromotive force being applied thereto.

20. The resistive-switching memory unit as claimed in claim 19, wherein the memory structure comprises at least one intermediate resistive state, the intermediate resistive state having a resistance between the first and the second resistive states.

21. The resistive-switching memory unit as claimed in claim 20, wherein the number of intermediate resistive states is dependent on the number of alternating paired switching layers within the device.

22. The resistive-switching memory unit as claimed in claim 21, wherein the number of intermediate states of the memory structure generally increases as the number of alternating paired switching layers in the memory structure is increased.

23. The resistive-switching memory unit as claimed in claim 1, wherein the resistive switching material comprises at least one particulate metal oxide layer in combination with at least one layer of a material selected from an organic material, a conductive organic material, a semi-conductive organic material, or a non-metal oxide inorganic material.

24. (canceled)

25. The resistive-switching memory unit as claimed in claim 23, wherein the at least one particulate metal oxide layer comprises particles of one or more conductive or semi-conductive organic or non-metal oxide inorganic materials.

26. The resistive-switching memory unit as claimed in claim 23, wherein at least one particulate metal oxide layer comprises one or more non-particulate conductive or semi-conductive organic or non-metal oxide inorganic materials.

27. The resistive-switching memory unit as claimed in claim 23, wherein at least one particulate metal oxide layer comprises one or more particulate or non-particulate organic or non-metal oxide inorganic materials.

28. A stretchable or deformable memory device as claimed in claim 6, wherein the device retains its memory performance after elongation or deformation.

29. A stretchable or deformable memory device as claimed in claim 6, wherein the device retains its memory function upon relaxation of the elastomeric or deformable substrate after an initial elongation or deformation.

30. A stretchable or deformable memory device as claimed in claim 6, wherein the device retains its memory performance after 10 cycles or more of elongation or deformation and relaxation of the elastomeric or deformable substrate.

31. (canceled)

32. A stretchable or deformable memory device as claimed in claim 6, wherein the device retains its memory performance after multiple cycles of elongation or deformation and relaxation of the elastomeric or deformable substrate and wherein the magnitude of elongation or deformation and relaxation of the substrate at each cycle is varied.
